(19) United States
(12) Patent Application Publication
(10) Pub. No.: US 2026/0032848 A1
(43) Pub. Date: Jan. 29, 2026

(54) SAFETY SLIDE RAIL DEVICE

(71) Applicant: FOSITEK CORPORATION, New Taipei City (TW)

(72) Inventors: Hsu-Hong YAO, New Taipei City (TW); Mo-Yu ZHANG, New Taipei City (TW)

(73) Assignee: FOSITEK CORPORATION, New Taipei City (TW)

(21) Appl. No.: 18/932,892

(22) Filed: Oct. 31, 2024

(30) Foreign Application Priority Data
Jul. 23, 2024 (TW) 113127575

(51) Int. Cl. H05K 7/14

(52) U.S. Cl. CPC H05K 7/1489

(57) ABSTRACT

A safety slide rail device includes an outer rail unit and an intermediate rail. The outer rail unit includes an outer rail that has a sliding surface, and a safety blocking member that is disposed on the sliding surface. The intermediate rail is slidably disposed on the sliding surface. The safety blocking member is frictionally engaged with the intermediate rail so as to impede sliding movement of the intermediate rail relative to the outer rail.

### CROSS-REFERENCE TO RELATED APPLICATION

This application claims priority to Taiwanese Invention patent application No. 113127575, filed on Jul. 23, 2024, the entire disclosure of which is incorporated by reference herein.

### FIELD

The disclosure relates to a slide rail device, and more particularly to a safety slide rail device.

### BACKGROUND

When an existing slide rail device is to be mounted to a server cabinet, because extension or retraction between slides of the existing slide rail device is unrestricted, a user may be injured by the existing slide rail device. Therefore, there is room for improvement of the existing slide rail assembly.

### SUMMARY

Therefore, an object of the disclosure is to provide a safety slide rail device that can alleviate at least one of the drawbacks of the prior art.

According to the disclosure, the safety slide rail device includes an outer rail unit and an intermediate rail.

The outer rail unit includes an outer rail that has a sliding surface, and a safety blocking member that is disposed on the sliding surface.

The intermediate rail is slidably disposed on the sliding surface.

The safety blocking member is frictionally engaged with the intermediate rail so as to impede sliding movement of the intermediate rail relative to the outer rail.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a perspective view illustrating a safety slide rail device according to an embodiment of the disclosure.

FIG. 2 is an exploded perspective view of the embodiment.

FIG. 3 is an enlarged fragmentary perspective view of the embodiment illustrating an outer rail unit of the safety slide rail device.

FIG. 4 is a sectional vie taken from line IV-IV from FIG. 1.

FIG. 5 is an enlarged fragmentary front view of the embodiment, illustrating an intermediate rail and an inner tail of the of the safety slide rail device being movable relative to the outer rail unit.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

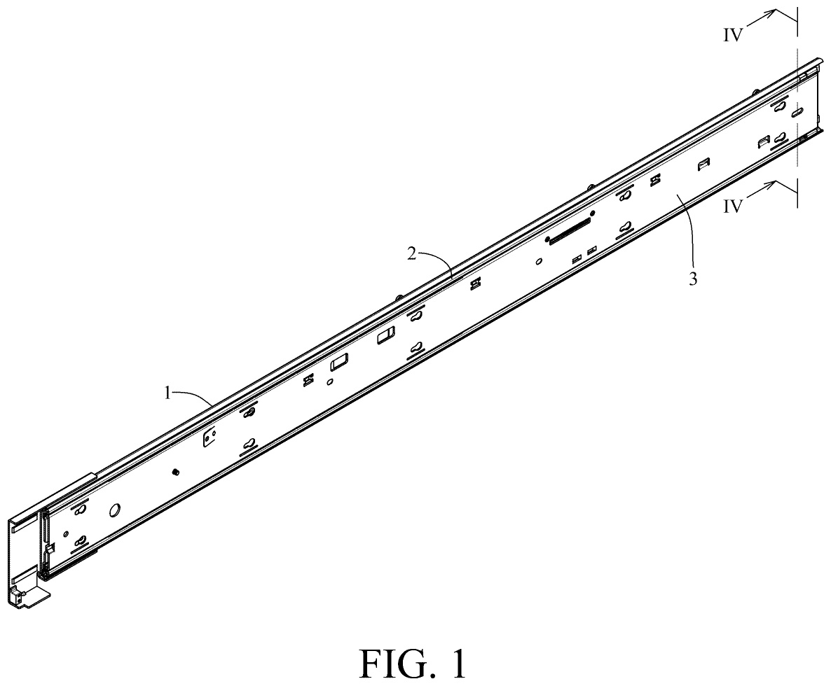

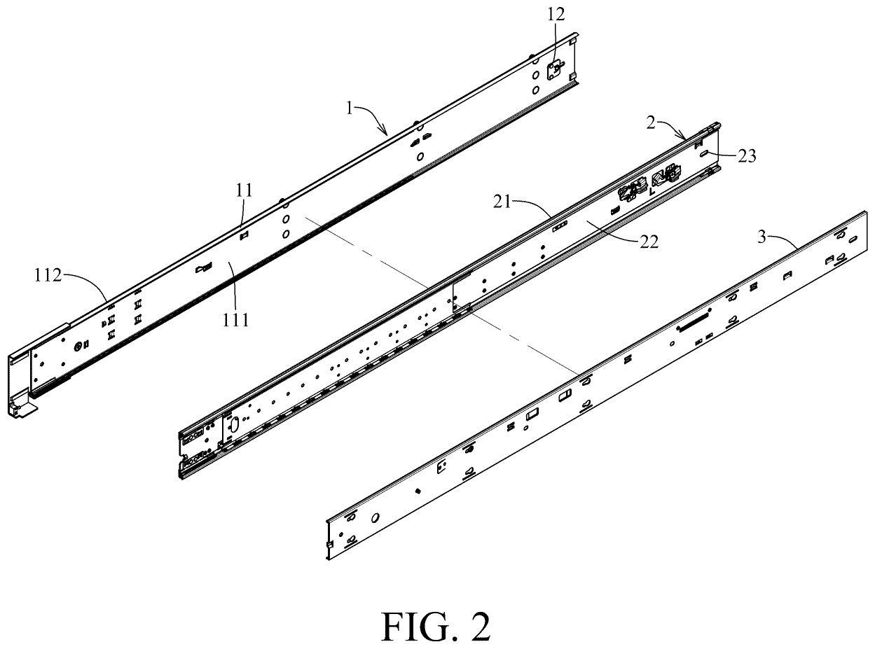

FIGS. 1 and 2 illustrate a safety slide rail device according to an embodiment of the disclosure, which is adapted to a server cabinet (not shown). The safety slide rail device includes an outer rail unit 1, an intermediate rail 2, and an inner rail 3.

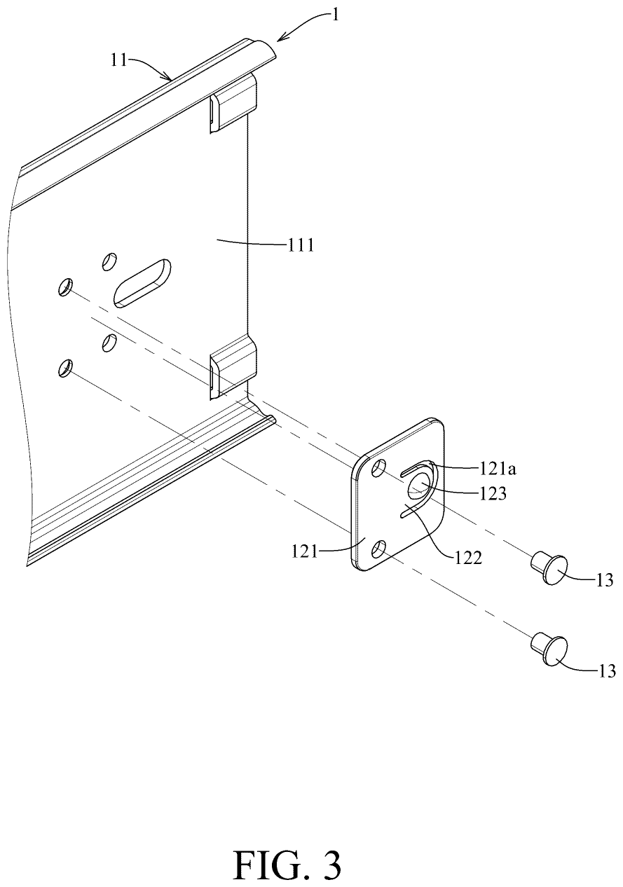

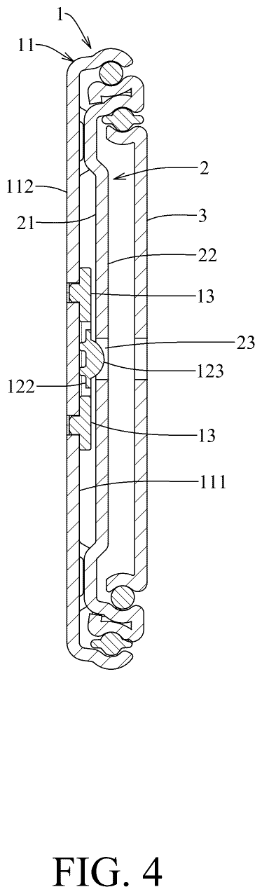

Referring to FIGS. 2 to 4, the outer rail unit 1 includes an outer rail 11 and a safety blocking member 12. The outer rail 11 has a sliding surface 111, and a mounting surface 112 that is opposite to the sliding surface 111 and that is configured to face the server cabinet (not shown). The safety blocking member 12 is fixed on the sliding surface 111 by two fasteners 13. In this embodiment, the safety blocking member 12 has a main body portion 121, a resilient arm portion 122, and a protrusion 123. The main body portion 121 is formed with an opening 121a. The resilient arm portion 122 extends from the main body portion 121 into the opening 121a. The protrusion 123 is formed on the resilient arm portion 122. Specifically, the safety protrusion 123 has, but not limited to, a dome surface. The safety blocking member 12 is, but not limited to be, made of one of a metal material and a plastic material.

The intermediate rail 2 is slidably disposed on the sliding surface 111 of the outer rail 11. When the intermediate rail 2 covers the safety blocking member 12, the safety blocking member 12 is in frictional contact with the intermediate rail 2 so as to impede sliding movement of the intermediate rail 2 relative to the outer rail 11. In this embodiment, the intermediate rail 2 has a first surface 21 that faces the outer rail 11, a second surface 22 that is opposite to the first surface 21, and an engaging recess 23 that extends through the first surface 21 and the second surface 22. When the protrusion 123 of the safety blocking member 12 is substantially aligned with the engaging recess 23 of the intermediate rail 2, the protrusion 123 of the safety blocking member 12 is resiliently and removably engaged with the engaging recess 23 of the intermediate rail 2.

The inner rail 3 is slidably disposed on the second surface 22.

When the protrusion 123 of the safety blocking member 12 is pressurized and disengaged from the engaging recess 23 such that the resilient arm portion 122 of the safety blocking member 12 is resiliently deformed, the intermediate rail 2 is slidable relative to the outer rail 11, and the protrusion 123 abuts against the first surface 21. When the protrusion 123 of the safety blocking member 12 is engaged with the engaging recess 23, or when the protrusion 123 the safety blocking member 12 abuts against the intermediate rail 2, the safety blocking member 12 is frictionally engaged with the intermediate rail 2 so as to impede sliding movement of the intermediate rail 2 relative to the outer rail 11. As a result, when the safety slide rail device of the disclosure is mounted to the server cabinet (not shown) by a user, and when the intermediate rail 2 covers the safety blocking member 12, because the safety blocking member 12 impedes the sliding movement of the intermediate rail 2 relative to the outer rail 11, the user is prevented from being injured.

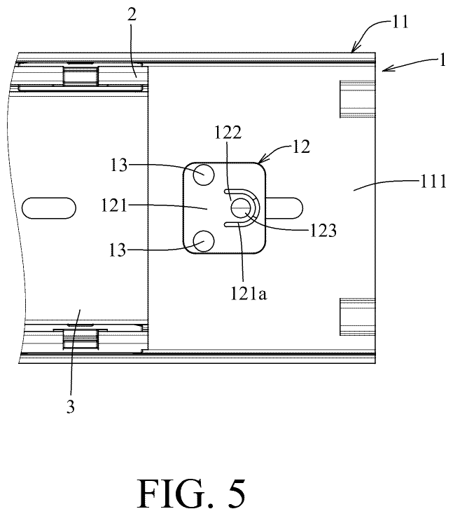

As shown in FIG. 5, as long as a pulling force from the user directly applied to the intermediate rail 2 and the inner rail 3 is sufficient to disengage the protrusion 123 from the engaging recess 23 and is greater than a force deforming the resilient arm portion 122 of the safety blocking member 12 such that the intermediate rail 2 is moved away from the safety blocking member 12, the intermediate rail 2 and the inner rail 3 may smoothly be pulled to slide relative to the outer rail 11.

In summary, when the intermediate rail 2 covers the safety blocking member 12, the safety blocking member 12 is frictionally engaged with the intermediate rail 2 so as to impede sliding movement of the intermediate rail 2 relative to the outer rail 11. When the safety slide rail device of the disclosure is mounted to the server cabinet by the user, the user may be prevented from being injured, thereby increasing safety for mounting the safety slide rail device of the disclosure.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A safety slide rail device comprising:
an outer rail unit including
an outer rail that has a sliding surface, and
a safety blocking member that is disposed on said sliding surface; and
an intermediate rail slidably disposed on said sliding surface;
wherein said safety blocking member is frictionally engaged with said intermediate rail so as to impede sliding movement of said intermediate rail relative to said outer rail.

2. The safety slide rail device as claimed in claim 1, wherein said safety blocking member has a protrusion in frictional contact with said intermediate rail.

3. The safety slide rail device as claimed in claim 2, wherein:
said safety blocking member further has
a main body portion that is formed with an opening, and
a resilient arm portion that extends from said main body portion into said opening; and
said protrusion is formed on said resilient arm portion.

4. The safety slide rail device as claimed in claim 1, wherein said safety blocking member is made of one of a metal material and a plastic material.

5. The safety slide rail device as claimed in claim 2, wherein said safety protrusion has a dome surface.

6. The safety slide rail device as claimed in claim 5, wherein:
said intermediate rail further has an engaging recess; and
said protrusion of said safety blocking member is resiliently and removably engaged with said engaging recess.
